(19) United States
(12) Patent Application Publication
(10) Pub. No.: US 2020/0273778 A1
(43) Pub. Date: Aug. 27, 2020

(54) Power Semiconductor Arrangement and Method for Fabricating a Power Semiconductor Arrangement

(71) Applicant: Infineon Technologies AG, Neubiberg (DE)

(72) Inventors: Juergen Hoegerl, Regensburg (DE); Tino Karczewski, Sinzing (DE); Michael Scheffer, Herrsching (DE); Christian Schweikert, Munich (DE)

(21) Appl. No.: 16/795,931

(22) Filed: Feb. 20, 2020

(30) Foreign Application Priority Data
Feb. 25, 2019 (DE) 102019104730.7

(51) Int. Cl. H01L 23/473; H01L 25/07; H01L 21/48; H01L 25/00

(52) U.S. Cl. CPC H01L 23/473; H01L 25/50; H01L 21/4882; H01L 25/073

(57) ABSTRACT

A power semiconductor arrangement includes first and second power semiconductor modules. Each power semiconductor module has a first main side and an opposing second main side. The power semiconductor modules are arranged such that a main side of the first power semiconductor module and a main side of the second power semiconductor module are facing each other. The power semiconductor arrangement further includes a cooler housing configured for direct liquid cooling of the power semiconductor modules. The cooler housing includes a fluid channel. At least one main side of the first power semiconductor module forms a sidewall of the fluid channel. A flow direction in the fluid channel along the first main side and a flow direction along the second main side of the first power semiconductor module are oriented in opposite directions.

### TECHNICAL FIELD

This disclosure relates in general to a power semiconductor arrangement and a method for fabricating a power semiconductor arrangement.

### BACKGROUND

Power semiconductor arrangements may comprise a plurality of power semiconductor modules which may be electrically coupled to one another to provide a desired circuit, e.g. a half bridge or an inverter, with the desired voltage and current range. The power semiconductor modules may produce a significant amount of heat during operation and power semiconductor arrangements may therefore comprise dedicated cooling measures. Liquid cooling measures, for example direct liquid cooling measures, may be particularly efficient for cooling a power semiconductor arrangement. However, such cooling measures may suffer from design complexity and/or bulky dimensions and/or stringent fabrication tolerances. Improved power semiconductor arrangements and improved methods for fabricating power semiconductor arrangements may help to overcome these and other problems.

The problem on which the invention is based is solved by the features of the independent claims. Further advantageous examples are described in the dependent claims.

### SUMMARY

Various aspects pertain to a power semiconductor arrangement comprising a first and a second power semiconductor module, wherein each power semiconductor module comprises a first main side and an opposing second main side and wherein the power semiconductor modules are arranged such that a main side of the first power semiconductor module and a main side of the second power semiconductor module are facing each other, and a cooler housing for direct liquid cooling of the power semiconductor modules, the cooler housing comprising a fluid channel, wherein at least one main side of the first power semiconductor module forms a sidewall of the fluid channel, and wherein a flow direction in the fluid channel along the first main side and a flow direction along the second main side of the first power semiconductor module are oriented in opposite directions.

Various aspects pertain to a method for fabricating a power semiconductor arrangement, the method comprising: providing at least two power semiconductor modules, wherein each power semiconductor module comprises a first main side and an opposing second main side, arranging the power semiconductor modules such that a main side of one power semiconductor module and a main side of another power semiconductor module are facing each other, and arranging a cooler housing for direct liquid cooling around the at least two power semiconductor modules, the cooler housing comprising a fluid channel, wherein at least one main side of the first power semiconductor module forms a sidewall of the fluid channel, and wherein a flow direction in the fluid channel along the first main side and a flow direction along the second main side of the first power semiconductor module is oriented in opposite directions.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Like reference numerals designate corresponding similar parts.

FIG. 1 shows a sectional view of a first power semiconductor arrangement comprising two power semiconductor modules and a cooler housing with a fluid channel.

FIGS. 2A and 2B show a perspective sectional view of a further power semiconductor arrangement, wherein the fluid channel reaches through an encapsulation body of the power semiconductor arrangement (FIG. 2A) and a section of the power semiconductor arrangement in greater detail (FIG. 2B).

FIG. 3 shows a perspective sectional view of a further power semiconductor arrangement, wherein the fluid channel is guided around lateral sides of the power semiconductor modules.

FIG. 4 shows a perspective sectional view of a further power semiconductor arrangement that comprises three inlets/outlets that may be configured for a symmetrical coolant fluid flow through the power semiconductor arrangement.

FIG. 5 shows the power semiconductor arrangement of FIG. 4 from another angle, wherein electrical contacts of the power semiconductor modules can be seen in FIG. 5.

FIGS. 6A and 6B show a perspective view (FIG. 6A) and a sectional view (FIG. 6B) of a power semiconductor module.

FIG. 7 shows a flow chart of a method for fabricating a power semiconductor arrangement.

### DETAILED DESCRIPTION

In the following description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration and is in no way limiting.

Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements co-operate or interact with each other regardless whether they are in direct physical or electrical contact, or they are not in direct contact with each other; intervening elements or layers may be provided between the “bonded”, “attached”, or “connected” elements.

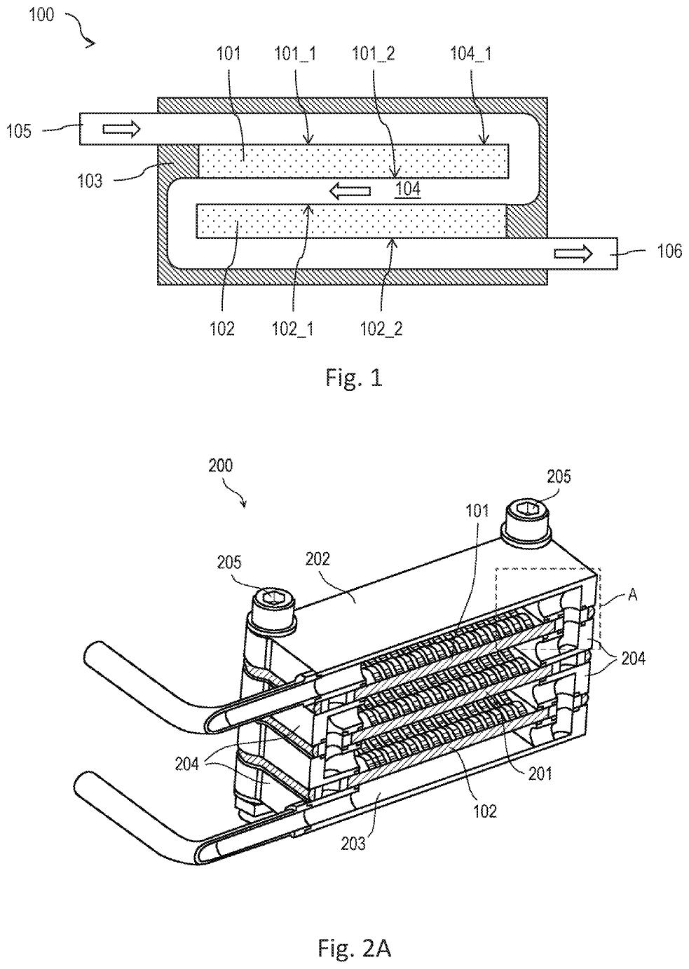

FIG. 1 shows a sectional view of a power semiconductor arrangement 100 comprising a first power semiconductor module 101 and a second power semiconductor module 102. The first power semiconductor module 101 comprises a first main side 101_1 and an opposing second main side 101_2 and the second power semiconductor module 102 as well comprises a first main side 102_1 and an opposing second main side 102_2. The power semiconductor modules 101, 102 are arranged such that the second main side 101_2 of the first power semiconductor module 101 and the first main side 102_1 of the second power semiconductor module 102 are facing each other. The power semiconductor arrangement 100 further comprises a cooler housing 103 for direct liquid cooling of the power semiconductor modules, the cooler housing 103 comprising a fluid channel 104. At least one main side (i.e. the first main side 101_1 or the second main side 101_2) of the first power semiconductor module 101 forms a sidewall of the fluid channel 104. A flow direction (indicated by the arrows in FIG. 1) in the fluid channel 104 along the first main side 101_1 and a flow direction along the second main side 101_2 of the first power semiconductor module 101 are oriented in opposite directions.

According to an example, additionally at least one main side (i.e. the first main side 102_1 or the second main side 102_2) of the second power semiconductor module 102 forms a sidewall of the fluid channel 104.

The power semiconductor modules 101, 102 may comprise a double sided cooling structure, wherein a first cooling structure, e.g. a DCB (direct copper bond), is arranged on the first main side 101_1 and another cooling structure, e.g. a further DCB, is arranged on the second main side 101_2. The power semiconductor modules 101, 102 may each comprise a half bridge circuit or an inverter circuit and may be configured to be electrically coupled. The power semiconductor modules 101, 102 may comprise power semiconductor chips with a vertical transistor structure, wherein a first power electrode of a power semiconductor chip faces the first main side 101_1 respectively 102_1, and wherein a second power electrode faces the second main side 101_2 respectively 102_2. Heat that is generated by the power semiconductor chips is transferred to the cooling structures, which in turn may be cooled by a coolant fluid flowing through the fluid channel 104.

A direct cooling scheme may be particularly efficient at cooling the power semiconductor modules 101, 102. The term “direct cooling” may denote a cooling scheme, wherein coolant fluid in the fluid channel 104 is in direct contact with an outer surface of the power semiconductor modules 101, 102, e.g. with the first main sides 101_1, 102_1 and/or the second main sides 101_2, 102_2. The alternative to direct cooling is indirect cooling, wherein the fluid channel 104 is indirectly coupled to the power semiconductor modules 101, 102 by arranging a layer of thermal interface material (TIM) between the fluid channel 104 and the power semiconductor modules 101, 102.

The cooler housing 103 may completely surround the power semiconductor modules 101, 102, except for external electrical contacts that may extend through an outer sidewall of the cooler housing 103. The external contacts may e.g. be power contacts like source contacts, drain contacts, emitter contacts or collector contacts, or gate contacts or sensing contacts.

The cooler housing 103 may comprise or consist of any suitable material, for example a metal like Al or Fe, a metal alloy, a ceramic or a polymer. The cooler housing 103 may comprise several individual parts that are fitted together to form the cooler housing, e.g. a bottom part, one or more middle parts and a top part. A size of the power semiconductor arrangement 100 may essentially be defined by the dimensions of the cooler housing 103. The power semiconductor arrangement may e.g. have dimensions of about 18 cm×18 cm×30 cm or about 10 cm×10 cm×10 cm.

In FIG. 1 the flow direction in the fluid channel 104 is shown to essentially run from the first power semiconductor module 101 to the second power semiconductor module 102. However, it is also possible that the opposite flow direction is used.

Parts of the fluid channel 104 that are arranged directly above or below the first main sides 101_1, 102_1 and/or the second main sides 101_2, 102_2 may have an extended width (perpendicular to the drawing plane of FIG. 1), such that the whole main sides or almost the whole main sides are covered by the fluid channel 104. Other parts of the fluid channel 104, which are not arranged directly above the main sides, may e.g. have an essentially circular cross section. Furthermore, the second main side 101_2 of the first power semiconductor module 101 and the first main side 102_1 of the second power semiconductor module may share the same cavity of the fluid channel 104 as shown in FIG. 1. According to another example, a dividing wall is arranged between the two main sides 101_2, 102_1 such that they are arranged in separate cavities of the fluid channel 104.

The power semiconductor arrangement 100 may comprise more than two power semiconductor modules, for example three or four power semiconductor modules. The additional power semiconductor modules may be stacked such that respective main sides are facing each other and the fluid channel 104 may meander between the power semiconductor modules as shown with respect to the power semiconductor modules 101 and 102 of FIG. 1.

The power semiconductor arrangement 100 may comprise a first inlet/outlet 105 of the fluid channel 104 which may e.g. be arranged above the topmost power semiconductor module (e.g. the first semiconductor module 101). The power semiconductor arrangement 100 may further comprise a second inlet/outlet 106 which may e.g. be arranged below the bottommost power semiconductor module (e.g. the second power semiconductor module 102).

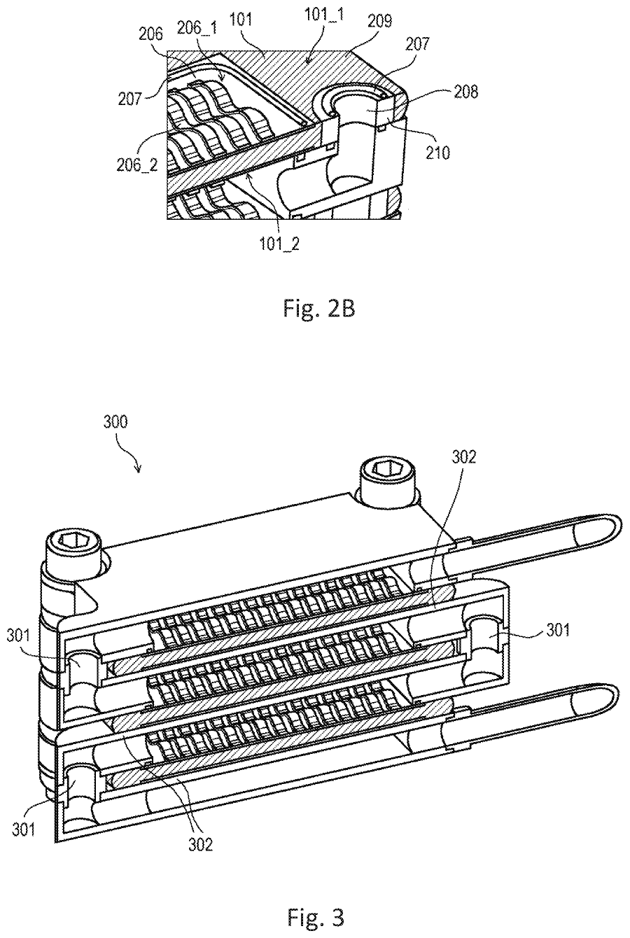

FIG. 2A shows a perspective sectional view of a further power semiconductor arrangement 200 which may be identical to the power semiconductor arrangement 100. Like reference signs may designate identical or similar parts.

The semiconductor arrangement 200 comprises the first and second power semiconductor modules 101, 102 and may also comprise a third power semiconductor module 201. The third power semiconductor module 201 may be arranged between the first and the second power semiconductor modules 101, 102. The power semiconductor modules 101, 102, 201 may be essentially identical (e.g. comprise identical circuitries) or they may be different from each other (e.g. comprise different circuitries).

According to an example, the power semiconductor modules 101, 102 and 201 may be stacked such that their outlines are arranged congruently as viewed e.g. from above the first main side 101_1.

The cooler housing 103 of power semiconductor arrangement 200 may comprise a top part 202, a bottom part 203 and middle parts 204 stacked between the top part 202 and the bottom part 203. The parts 202, 203 and 204 of the cooler housing 103 may be held together using suitable fastening means, e.g. screws 205. The screws 205 may e.g. be arranged at the four corners of the cooler housing 103.

FIG. 2B shows the section A of FIG. 2A in greater detail. In order to present a clearer view of the power semiconductor module 101, the top part 202 of the cooler housing 103 is not shown in FIG. 2B.

The semiconductor power module 101 may comprise a cooling structure 206 arranged on the first main side 101_1. The cooling structure 206 may e.g. comprise a base plate 206_1 (e.g. a metal base plate) and/or a plurality of cooling fins 206_2. The cooling fins 206_2 may extend into the fluid channel 104 and they may be configured to slow down a fluid speed along the fluid channel 104. The cooling fins 206_2 may thereby create turbulences in the coolant fluid which may help to dissipate heat from the power semiconductor module 101 into the coolant fluid. According to an example, the cooling fins 206_2 comprise or consist of metallic ribbons. The ribbons may span arcs over the first main side 101_1, wherein a flow direction in the fluid channel 104 may be perpendicular to the arcs.

The power semiconductor arrangement 200 may further comprise seal rings 207 arranged on the first main side 101_1. For example, a first seal ring 207 may be arranged around the cooling fins 206_2 and a second seal ring 207 may be arranged around a through-hole 208 that connects the first main side 101_1 with the second main side 101_2. The seal rings 207 may e.g. comprise or consist of a polymer. The seal rings 207 may be dispensed seal rings, deposited on the first main side 101_1 using a dispensing tool. However, the seal rings 207 may also be solid bodies that are arranged on the first main side 101_1 using a pick-and-place process.

The seal rings 207 may be configured to seal the fluid channel and the seal rings 207 may be further configured to compensate for unevenness or warping due to fabrication tolerances of the power semiconductor modules 101, 102 and 201 or of the cooler housing parts 202, 203 and 204.

According to the example shown in FIGS. 2A and 2B, the through-holes 208 may extend through an encapsulation body 209 of the first semiconductor module 101. The through-holes 208 may comprise an annular piece 210 that is embedded in the encapsulation body 209. The annular piece 210 may comprise or consist of the same material as the cooler housing 103. A seal ring 207 may be arranged on the annular piece 210. The annular piece 210 may connect a part of the fluid channel 104 that is arranged along the first main side 101_1 of the power semiconductor module 101 with a further part of the fluid channel 104 that is arranged along the second main side 101_2.

According to an example, the second main side 101_2 of the power semiconductor module 101 is built similar or identical to the first main side 101_1, i.e. the second main side 101_2 may as well comprise the above-mentioned cooling structure 206_1, 206_2 and seal rings 207. According to an example, the second power semiconductor module 102 and the third power semiconductor module 201 may be built similar or identical to the first power semiconductor module 101 as described above.

FIG. 3 shows a perspective sectional view of a further power semiconductor arrangement 300 which may be identical to the power semiconductor arrangements 100 and 200 except for the differences described in the following. Like reference signs may designate identical or similar parts.

In the power semiconductor arrangement 200 shown in FIGS. 2A and 2B, the through-holes 208 extend through the encapsulation body 209 of the power semiconductor modules 101, 102 and 201. In the power semiconductor arrangement 300 the fluid channel 104 does not extend through the encapsulation bodies 209 but instead is laterally guided around the power semiconductor modules 101, 102 and 201. In other words, a connecting part 301 that connects e.g. a part of the fluid channel 104 that extends along the first main side 101_1 to a further part of the fluid channel 104 that extends along the second main side 101_2 is not integrated into the first power semiconductor module 101. The connecting part 301 instead is only a part of the cooler housing 103.

Furthermore, in the power semiconductor arrangement 300 only one main side of each of the power semiconductor modules 101, 102, 201 is directly cooled (i.e. is in direct contact with a coolant fluid in the fluid channel 104). The other main side of each of the power semiconductor modules 101, 102, 201 is indirectly cooled (i.e. is not in direct contact with the coolant fluid). The middle parts 204 and the bottom part 203 of the cooler housing comprise sidewalls 302 which seal the fluid channel 104 off towards the respective main sides of the power semiconductor modules 101, 102, 201. A layer of thermal interface material may be arranged between the sidewalls 302 and the respective main sides to ensure a good thermal coupling between the respective main sides and the fluid channel 104.

In power semiconductor arrangement 300 those main sides of the power semiconductor modules 101, 102 and 201 that are facing the sidewalls 302 of the fluid channel 104 may not comprise any cooling fins 206_2.

According to an example, the power semiconductor module 300 does not comprise the sidewalls 302, meaning that both main sides of the power semiconductor modules 101, 102 and 201 are configured for direct cooling. It is also possible that at least one power semiconductor module is configured for direct cooling on both main sides and at least one other power semiconductor module is configured for indirect cooling on at least one main side.

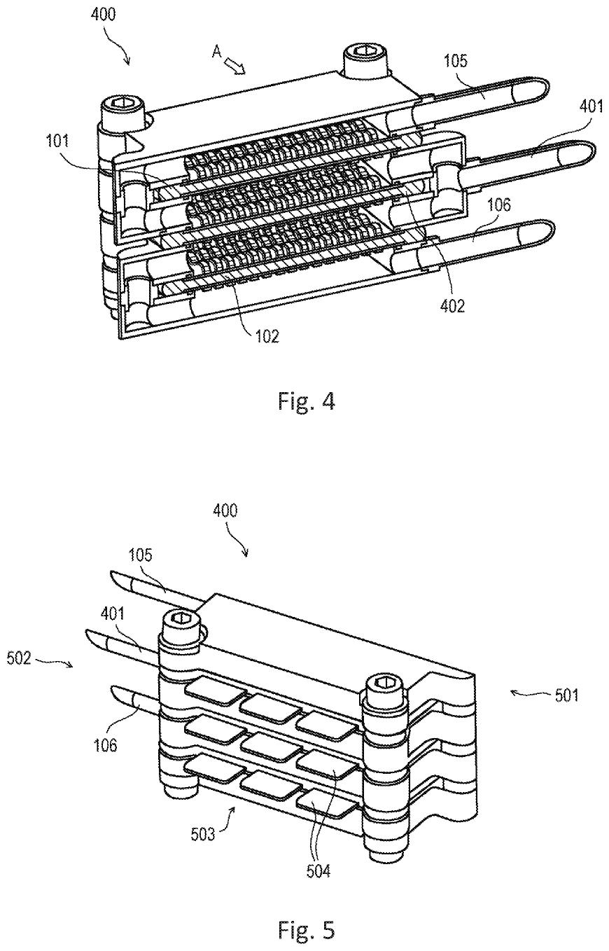

FIG. 4 shows a perspective sectional view of a further power semiconductor arrangement 400 which may be identical to the power semiconductor arrangement 300 except for the differences described in the following. Like reference signs may designate identical or similar parts.

The power semiconductor arrangement 400 comprises the first inlet/outlet 105 and the second inlet/outlet 106. The power semiconductor arrangement 400 further comprises a third inlet/outlet 401. The third inlet/outlet 401 may be arranged between the first and the second inlets/outlets 105, 106, in particular symmetrically between the first and second inlets/outlets 105, 106. The third inlet/outlet 401 may be arranged on the same side as the first and second inlets/outlets 105, 106 (as shown in FIG. 4) or it may be arranged at an opposite side of the power semiconductor arrangement 400.

In the example shown in FIG. 4 the power semiconductor arrangement 400 comprises the first, second and third power semiconductor modules 101, 102 and 201. According to an example, the power semiconductor arrangement 400 may as well comprise a fourth power semiconductor module. The fourth power semiconductor module may be identical to at least one of the power semiconductor modules 101, 102 and 201. The third inlet/outlet 401 may be arranged between opposing main sides of the third and fourth power semiconductor modules.

According to another example, the power semiconductor arrangement 400 comprises only the first, second and third power semiconductor modules 101, 102 and 201. In this case the third inlet/outlet 401 may be arranged such that it faces a lateral side of the third (middle) power semiconductor module 201 (wherein the lateral side connects the first and second main sides). According to yet another example, the power semiconductor arrangement 400 comprises only the first and second power semiconductor modules 101, 102 and the third inlet/outlet 401 is arranged between the two.

According to an example, the first and second inlets/outlets 105, 106 may be used as solely as outlets and the third inlet/outlet 401 may be used solely as inlet. According to another example, the first and second inlets/outlets 105, 106 may be used solely as inlets and the third inlet/outlet 401 may be used solely as outlet.

The symmetrical arrangement of the inlet(s) and outlet(s) of power semiconductor arrangement 400 may help to distribute a pressure drop of the coolant fluid in the fluid channel 104 more evenly over the power semiconductor modules 101, 102, 201 and 402 as compared to e.g. the power semiconductor arrangements 100 to 300. The symmetrical arrangement may also help to distribute a temperature increase of the coolant fluid more evenly over the power semiconductor modules 101, 102 and 201. The symmetrical arrangement may help to ensure that the power semiconductor modules 101, 102 and 201 are cooled with the same or about the same efficiency.

In the power semiconductor arrangement 400 all main sides of the power semiconductor modules 101, 102 and 201 may be configured for direct cooling as shown in FIG. 4 or some main sides may be configured for indirect cooling as described further above.

FIG. 5 shows the sectional view of the power semiconductor arrangement 400 along the arrow A in FIG. 4 (that is, from the backside in FIG. 4). The power semiconductor arrangement 400 comprises a first lateral side 501 and an opposite second lateral side 502. The first, second and third inlets/outlets 105, 106 and 401 may be arranged at the first and second lateral sides 501, 502, respectively. The power semiconductor arrangement 400 further comprises a third lateral side 503 (and a fourth lateral side, not shown in FIG. 5). The power semiconductor arrangement 400 may comprise a plurality of electrical contacts 504 arranged at the third lateral side 503. According to an example, contacts 504 may also be arranged at the fourth lateral side.

The contacts 504 may be configured for electrically contacting the power semiconductor modules 101, 102, 201 and 402 from the outside. The contacts 504 may comprise power contacts and control contacts. The control contacts may be configured to be coupled to a driver board.

According to an example, the power semiconductor arrangements 100, 200 and 300 comprise a similar arrangement of contacts 504 as shown with respect to the power semiconductor arrangement 400.

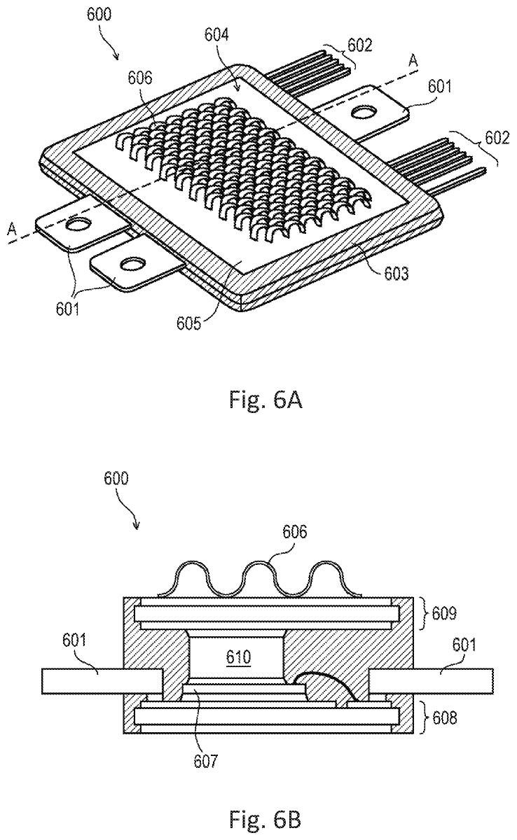

FIG. 6A shows a perspective view of a power semiconductor module 600. The power semiconductor module 600 may be identical to at least one of the power semiconductor modules 101, 102, 201 and 402.

The power semiconductor module 600 may e.g. comprise a half bridge circuit or an inverter circuit. The power semiconductor module 600 comprises power contacts 601 and control or gauging contacts 602. The power contacts 601 may e.g. comprise a source contact, a drain contact and a phase contact. The control or gauging contacts 602 may comprise a gate contact and/or a temperature sensor contact. The contacts 601, 602 may be arranged at opposite lateral sides of the power semiconductor module 600.

The power semiconductor module 600 comprises an encapsulation body 603, e.g. a molded material. A cooling structure may be exposed at the encapsulation body 603 on a main side 604 of the power semiconductor module 600. The cooling structure may comprise a (metal) base plate 605 and/or cooling fins 606. The cooling fins 606 may comprise or consist of (metal) ribbons that span arcs over the main side 604.

According to an example, both main sides 604 of the power semiconductor module 600 comprise the base plate 605 and/or the cooling fins 606. According to another example, one main side 604 comprises the base plate 605 and/or the cooling fins 606 and the opposite main side 604 does not comprise the cooling fins 606 (that is, one main side 604 is configured for direct liquid cooling and the other main side 604 is configured for indirect cooling).

FIG. 6B shows a sectional view of the power semiconductor module 600 along the line A-A in FIG. 6A. The power semiconductor module 600 may comprise one or more semiconductor chips 607, a first carrier 608 and a second carrier 609. The semiconductor chip 607 may be a power semiconductor chip and may e.g. be a MOSFET (metal-oxide-semiconductor field-effect transistor) or an IGBT (insulated gate bipolar transistor). The semiconductor chip(s) 607 may comprise a vertical transistor structure, wherein one electrode faces the first carrier 608 and another electrode faces the second carrier 609. The semiconductor chip(s) 607 may be manufactured from specific semiconductor material, for example Si, SiC, SiGe, GaAs, and GaN or from any other suitable semiconductor material.

The first carrier 608 and/or the second carrier 609 may for example be a DCB, a DAB (direct aluminum bond), an AMB (active metal braze) or a leadframe.

The semiconductor chip 607 may be arranged on the first carrier 608 and it may be thermally and/or mechanically and/or electrically coupled to the second carrier 609 via a spacer 610.

According to an example, a bigger part (e.g. 60%) of the heat that is produced by the semiconductor chip 607 may be dissipated via the first carrier 608 and a smaller part (e.g. 40%) of the heat is dissipated via the second carrier 609. It may therefore be more important to provide efficient cooling (e.g. direct liquid cooling) of the first carrier 608 than of the second carrier 609 (which may e.g. be indirectly cooled).

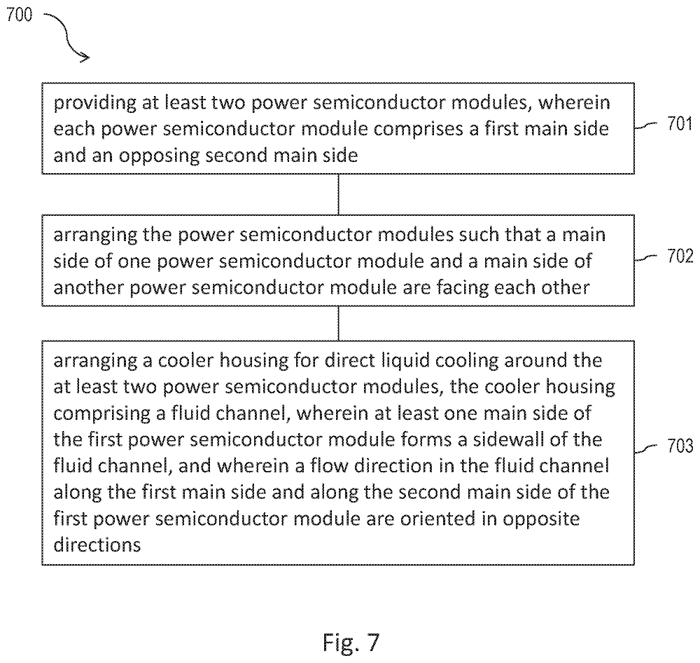

FIG. 7 shows a flow chart of a method 700 for fabricating a power semiconductor arrangement. The method 700 comprises at 701 providing at least two power semiconductor modules, wherein each power semiconductor module comprises a first main side and an opposing second main side, at 702 arranging the power semiconductor modules such that a main side of one power semiconductor module and a main side of another power semiconductor module are facing each other, and at 703 arranging a cooler housing for direct liquid cooling around the at least two power semiconductor modules, the cooler housing comprising a fluid channel, wherein at least one main side of the first power semiconductor module forms a sidewall of the fluid channel, and wherein a flow direction in the fluid channel along the first main side and along the second main side of the first power semiconductor module are oriented in opposite directions.

According to an example, the method 700 may comprise that a first inlet/outlet of the fluid channel is arranged at the first main side of the first power semiconductor module and a second inlet/outlet of the fluid channel is arranged at the second main side of the second power semiconductor module, such that the fluid channel meanders in the power semiconductor arrangement, wherein a flow direction in the fluid channel along the first main side and along the second main side of each power semiconductor module are oriented in opposite directions.

The method 700 may further comprise sealing the fluid channel with seal rings. The method 700 may comprise dispensing the seal rings on individual stacked elements of the cooler housing. The seal rings may seal the fluid channel between the individual stacked elements.

In the following, the power semiconductor arrangement and the method for fabricating a power semiconductor arrangement will be further explained using particular examples.

Example 1 is a power semiconductor arrangement, comprising a first and a second power semiconductor module, wherein each power semiconductor module comprises a first main side and an opposing second main side and wherein the power semiconductor modules are arranged such that a main side of the first power semiconductor module and a main side of the second power semiconductor module are facing each other, and a cooler housing for direct liquid cooling of the power semiconductor modules, the cooler housing comprising a fluid channel, wherein at least one main side of the first power semiconductor module forms a sidewall of the fluid channel, and wherein a flow direction in the fluid channel along the first main side and a flow direction along the second main side of the first power semiconductor module are oriented in opposite directions.

Example 2 is the power semiconductor arrangement of example 1, wherein a first inlet/outlet of the fluid channel is arranged at the first main side of the first power semiconductor module and a second inlet/outlet of the fluid channel is arranged at the second main side of the second power semiconductor module, such that the fluid channel meanders in the power semiconductor arrangement, wherein a flow direction in the fluid channel along the first main side and a flow direction along the second main side of each power semiconductor module are oriented in opposite directions.

Example 3 is the power semiconductor arrangement of example 2, further comprising a third inlet/outlet of the fluid channel arranged between the first and second power semiconductor modules.

Example 4 is the power semiconductor arrangement of one of the preceding examples, wherein the first and/or second power semiconductor module comprises an encapsulation body and wherein the fluid channel extends through at least one through-hole in the encapsulation body.

Example 5 is the power semiconductor arrangement of one of the preceding examples, wherein the cooler housing comprises individual stacked elements and wherein seal rings are used to seal the fluid channel between the individual stacked elements.

Example 6 is the power semiconductor arrangement of example 5, wherein the seal rings are dispensed seal rings, fabricated using a dispensing tool.

Example 7 is the power semiconductor arrangement of one of the preceding examples, wherein both main sides of the first and/or second power semiconductor module form a respective sidewall of the fluid channel.

Example 8 is the power semiconductor arrangement of one of examples 1 to 6, wherein only one main side of each power semiconductor module forms a sidewall of the fluid channel and wherein a layer of thermal interface material is arranged between the other main side of each power semiconductor module and the fluid channel.

Example 9 is the power semiconductor arrangement of one of the preceding examples, wherein the first and/or second power semiconductor module comprises cooling fins that extend into the fluid channel.

Example 10 is the power semiconductor arrangement of example 9, wherein the cooling fins comprise or consist of metallic ribbons.

Example 11 is the power semiconductor arrangement of example 9 or 10, wherein the individual power semiconductor modules comprise different arrangements of the cooling fins, in particular wherein the ribbon arrangement is configured to slow down a fluid speed along the fluid channel.

Example 12 is the power semiconductor arrangement of one of the preceding examples, wherein each power semiconductor module comprises external contacts that are exposed at a lateral side of the cooler housing.

Example 13 is the power semiconductor arrangement of example 12, wherein each power semiconductor module comprises external contacts on opposing lateral sides and wherein the external contacts are exposed at opposing lateral sides of the cooler housing.

Example 14 is a method for fabricating a power semiconductor arrangement, the method comprising providing at least two power semiconductor modules, wherein each power semiconductor module comprises a first main side and an opposing second main side, arranging the power semiconductor modules such that a main side of one power semiconductor module and a main side of another power semiconductor module are facing each other, and arranging a cooler housing for direct liquid cooling around the at least two power semiconductor modules, the cooler housing comprising a fluid channel, wherein at least one main side of the first power semiconductor module forms a sidewall of the fluid channel, and wherein a flow direction in the fluid channel along the first main side and a flow direction along the second main side of the first power semiconductor module is oriented in opposite directions.

Example 15 is the method of claim 14, further comprising arranging a first inlet/outlet of the fluid channel at the first main side of the first power semiconductor module and arranging a second inlet/outlet of the fluid channel at the second main side of the second power semiconductor module, such that the fluid channel meanders in the power semiconductor arrangement, wherein a flow direction in the fluid channel along the first main side and a flow direction along the second main side of each power semiconductor module are oriented in opposite directions.

Example 16 is the method of example 14 or 15, further comprising dispensing seal rings on individual stacked elements of the cooler housing to seal the fluid channel between the individual stacked elements.

Example 17 is an apparatus comprising means for performing the method according to one of the examples 14 to 16.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor arrangement, comprising:
a first power semiconductor module and a second power semiconductor module, wherein each power semiconductor module comprises a first main side and an opposing second main side, and wherein the first and the second power semiconductor modules are arranged such that a main side of the first power semiconductor module and a main side of the second power semiconductor module are facing each other; and
a cooler housing configured for direct liquid cooling of the first and the second power semiconductor modules, the cooler housing comprising a fluid channel,
wherein at least one main side of the first power semiconductor module forms a sidewall of the fluid channel,
wherein a flow direction in the fluid channel along the first main side and a flow direction along the second main side of the first power semiconductor module are oriented in opposite directions.

2. The power semiconductor arrangement of claim 1, wherein a first inlet/outlet of the fluid channel is arranged at the first main side of the first power semiconductor module and a second inlet/outlet of the fluid channel is arranged at the second main side of the second power semiconductor module, such that the fluid channel meanders in the power semiconductor arrangement, and wherein a flow direction in the fluid channel along the first main side and a flow direction along the second main side of each power semiconductor module are oriented in opposite directions.

3. The power semiconductor arrangement of claim 2, further comprising:
a third inlet/outlet of the fluid channel arranged between the first and the second power semiconductor modules.

4. The power semiconductor arrangement of claim 1, wherein the first power semiconductor module and/or the second power semiconductor module comprises an encapsulation body, and wherein the fluid channel extends through at least one through-hole in the encapsulation body.

5. The power semiconductor arrangement of claim 1, wherein the cooler housing comprises individual stacked elements, and wherein seal rings are used to seal the fluid channel between the individual stacked elements.

6. The power semiconductor arrangement of claim 5, wherein the seal rings are dispensed seal rings, fabricated using a dispensing tool.

7. The power semiconductor arrangement of claim 1, wherein both main sides of the first power semiconductor module and/or the second power semiconductor module form a respective sidewall of the fluid channel.

8. The power semiconductor arrangement of claim 1, wherein only one main side of each power semiconductor module forms a sidewall of the fluid channel, and wherein a layer of thermal interface material is arranged between the other main side of each power semiconductor module and the fluid channel.

9. The power semiconductor arrangement of claim 1, wherein the first power semiconductor module and/or the second power semiconductor module comprises cooling fins that extend into the fluid channel.

10. The power semiconductor arrangement of claim 9, wherein the cooling fins comprise metallic ribbons.

11. The power semiconductor arrangement of claim 9, wherein the first power semiconductor module and the second power semiconductor module comprise different arrangements of the cooling fins such that a ribbon arrangement of the cooling fins is configured to slow down a fluid speed along the fluid channel.

12. The power semiconductor arrangement of claim 1, wherein each power semiconductor module comprises external contacts that are exposed at a lateral side of the cooler housing.

13. The power semiconductor arrangement of claim 12, wherein each power semiconductor module comprises external contacts on opposing lateral sides, and wherein the external contacts are exposed at opposing lateral sides of the cooler housing.

14. A method for fabricating a power semiconductor arrangement, the method comprising:
providing at least two power semiconductor modules, wherein each power semiconductor module comprises a first main side and an opposing second main side;
arranging the at least two power semiconductor modules such that a main side of a first power semiconductor module and a main side of a second power semiconductor module are facing each other; and
arranging a cooler housing for direct liquid cooling around the at least two power semiconductor modules, the cooler housing comprising a fluid channel,
wherein at least one main side of the first power semiconductor module forms a sidewall of the fluid channel,
wherein a flow direction in the fluid channel along the first main side and a flow direction along the second main side of the first power semiconductor module is oriented in opposite directions.

15. The method of claim 14, further comprising:
arranging a first inlet/outlet of the fluid channel at the first main side of the first power semiconductor module and arranging a second inlet/outlet of the fluid channel at the second main side of the second power semiconductor module, such that the fluid channel meanders in the power semiconductor arrangement,
wherein a flow direction in the fluid channel along the first main side and a flow direction along the second main side of each power semiconductor module are oriented in opposite directions.

16. The method of claim 15, further comprising:
arranging a third inlet/outlet of the fluid channel arranged between the first and the second power semiconductor modules.

17. The method of claim 14, further comprising:
dispensing seal rings on individual stacked elements of the cooler housing to seal the fluid channel between the individual stacked elements.

18. The method of claim 17, wherein the seal rings are fabricated using a dispensing tool.
